(19) United States
(12) Patent Application Publication
(10) Pub. No.: US 2026/0130132 A1
(43) Pub. Date: May 7, 2026

(54) DIAGONAL-TYPE PHASE CHANGE MEMORY CELL

(71) Applicant: International Business Machines Corporation, Armonk, NY (US)

(72) Inventors: Ghazi Sarwat Syed, Kilchberg (CH); Vara Sudananda Prasad Jonnalagadda, Wallisellen (CH); Timothy Mathew Philip, Albany, NY (US); Abu Sebastian, Adliswil (CH)

(21) Appl. No.: 18/936,224

(22) Filed: Nov. 4, 2024

(51) Int. Cl. H10N 70/00; H10B 63/10; H10N 70/20

(52) U.S. Cl. CPC H10N 70/8265; H10B 63/10; H10N 70/066; H10N 70/231; H10N 70/8418

(57) ABSTRACT

A phase change material (PCM) memory cell having a diagonal-shaped “ultrathin phase change film” channel structure approaching sub-5 nm that makes edge contact with two side electrodes, and a point contact with an ultra-thin bottom-electrode provisioned in the middle. The formed PCM memory structure includes an “angled substrate” on which the phase-change film is deposited such that the substrate is optimally etched at angles up to and exceeding 55 degrees, enabling long phase-change material channels at reduced lateral areal footprints. The diagonal-shaped ultrathin phase change film structure simultaneously enables very low programming energies in devices while achieving a small area footprint.

### BACKGROUND

The present application relates to a memory structure, and more particularly to a diagonal-type phase change material (PCM) memory structure, its method of manufacture, and its operation.

Phase change materials (PCMs) have been pursued for a variety of applications such as, for example, storage class memory as well as storing weights of neural networks for artificial intelligence and in-memory computing. In typical PCMs formed as disc cell memory structures, the amount of PCM to melt and change phase can be relatively large requiring one or more high and/or long current pulses to melt the appropriate amount of PCM. This high and/or longer current duration can consume relatively large amounts of energy and use relatively large amounts of power.

It is highly desirable to increase the PCM energy efficiency and decrease the footprint of the PCM memory device.

### SUMMARY

A PCM device of a structure comprising an angled geometry.

A PCM device of a structure comprising an angled geometry that achieves a large aspect ratio.

A PCM device of a structure comprising an angled geometry that achieves a large aspect ratio with bottom electrode point of contact, i.e., the device structure enables a point contact between the PCM channel and the electrode, providing high programming efficiencies.

A PCM cell device of a structure comprising a small base with a long PCM channel, wherein the PCM channel is increased without increasing the footprint of the device.

In one aspect of the present disclosure, there is provided a phase change memory cell. The phase change memory cell comprises: a first dielectric material layer; a first electrode formed above the first dielectric material layer; a second dielectric material layer formed above the first electrode; a further dielectric material structure having a first sidewall surface portion abutting a side edge of the first dielectric material layer and a second sidewall surface portion abutting a side edge of the second dielectric material layer; and a phase change material (PCM) layer having a first PCM layer portion formed on a top surface of the second dielectric material layer and having an angled PCM layer portion extending from the first PCM layer portion at an angle within the further dielectric material structure and having a slanted surface, the first electrode having an edge electrically contacting the slanted surface of the angled PCM layer

In a further aspect, there is provided a phase change memory cell structure. The phase change memory cell structure comprises: a first dielectric material layer; a first electrode formed above the first dielectric material layer; a second dielectric material layer formed above the first electrode; a further dielectric material structure having a first sidewall surface portion abutting a side edge of the first dielectric material layer and a second sidewall surface portion abutting a side edge of the second dielectric material layer; a phase change material (PCM) layer having a first PCM layer portion formed on a top surface of said second dielectric material layer and having an angled PCM layer portion extending from the first PCM layer portion at an angle within said further dielectric material structure and having a second PCM layer portion extending from said angled PCM layer portion within said further dielectric material structure, said angled PCM layer having a slanted surface, wherein an edge of the first electrode electrically contacts the slanted surface of the angled PCM layer; and a second electrode having a first end electrically contacting the first PCM layer portion and having a second end electrically contacting the second PCM layer portion within said further dielectric material structure

In a further embodiment, there is provided a method of forming a phase change memory cell. The method comprises: providing a first dielectric material layer having a first portion of a first thickness and a second portion of a second thickness; forming a bottom electrode on top of the first portion of the first dielectric material layer, the bottom electrode having a surface that is coplanar with a surface of the second portion of the first dielectric material layer; forming a capping dielectric material layer on top the coplanar surface, the capping dielectric material layer of a width covering an interface between a sidewall edge of the bottom electrode and the second portion of the first dielectric material layer; forming a second dielectric material layer on top of the bottom electrode, wherein a length of the second dielectric material layer is of a length less than the length of the bottom electrode, the second dielectric material layer having a surface coplanar with a surface of the capping dielectric material layer; performing a reactive ion etch at a defined angle to form an opening extending through the capping layer and the first dielectric material layer, the opening having a continuous slanted sidewall surface comprising a slanted sidewall surface portion of the capping dielectric material layer and a slanted sidewall surface portion of the first dielectric material layer, the angled etch exposing an edge of the bottom electrode on the continuous slanted sidewall surface; and depositing a phase change material (PCM) layer on top the continuous slanted sidewall surface to form an angled PCM layer, whereby the edge of the first electrode electrically contacts the slanted surface of the angled PCM layer.

The foregoing and other objects, features and advantages of the invention will be apparent from the following more particular descriptions of exemplary embodiments of the invention as illustrated in the accompanying drawings.

### BRIEF DESCRIPTION OF THE DRAWINGS

The various aspects, features, and embodiments of PCM memory structures; methods or techniques for making PCM memory structures; and/or the operation and function of PCM memory structures will be better understood when read in conjunction with the figures provided. It may be noted that a numbered element in the figures is typically numbered according to the figure in which the element is introduced, is typically referred to by that number throughout succeeding figures, and that like reference numbers generally represent like parts of exemplary embodiments of the invention.

Embodiments are provided in the figures for the purpose of illustrating aspects, features, and/or various embodiments of the memory structure, e.g., PCM memory structure; methods and techniques for making the memory structure, and/or the operation and function of the memory structure, but the claims should not be limited to the precise arrangement, structures, layers, features, materials, aspects, assemblies, subassemblies, functional units, embodiments, methods, processes, or devices shown.

FIG. 1A depicts a cross-sectional view of an exemplary phase change material (PCM) memory device according to a first embodiment of the present disclosure;

FIG. 1B shows a cross-sectional view of the exemplary phase change material (PCM) memory device according to a second embodiment of the present disclosure;

FIG. 2 shows a cross-sectional view of an exemplary PCM memory device structure according to a further embodiment of the present disclosure;

FIGS. 3A-3C depict cross-sectional elevational views of an alternate embodiment of a PCM memory cell including diagonal shaped PCM cell for improved programming efficiencies; and

FIGS. 4A-4H depict a method for constructing a phase change memory device structure according to the embodiments of the present disclosure

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. In addition, features described herein can be used in combination with other described features in each of the various possible combinations and permutations. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

Unless otherwise specifically defined herein, all terms are to be given their broadest possible interpretation including meanings implied from the specification as well as meanings understood by those skilled in the art and/or as defined in dictionaries, treatises, etc. It should also be noted that, as used in the specification and the appended claims, the singular forms “a”, “an” and “the” include plural referents unless otherwise specified, and that the terms “includes”, “comprises”, and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath”, “directly under”, or “in contact with” another element, there are no intervening elements present.

The present disclosure is directed to an energy efficient phase change material (PCM) memory structure and/or device, and more particularly, to a PCM structure having an angled geometry that achieves a large aspect ratio with bottom electrode point of contact, i.e., the device structure enables a point contact between the PCM channel and the electrode

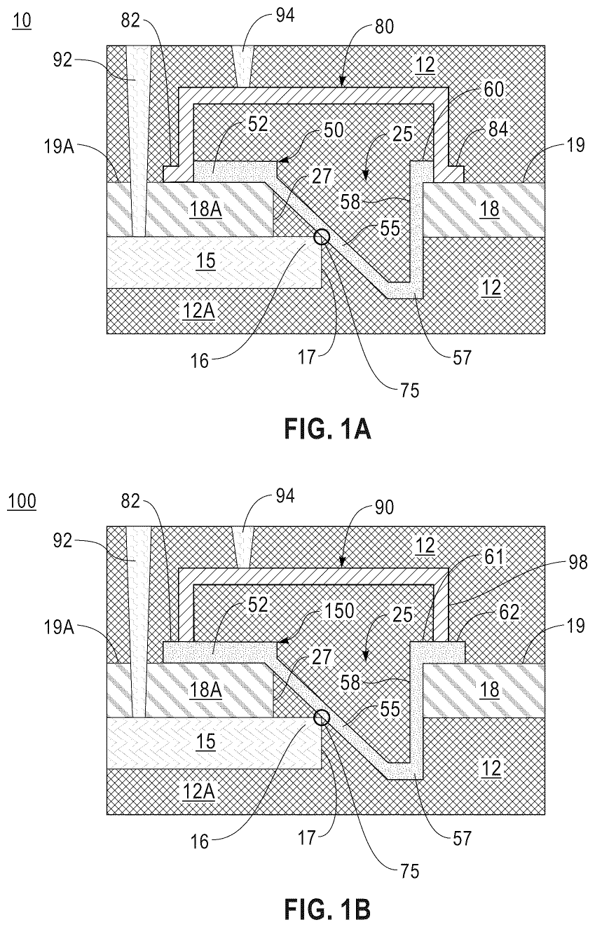

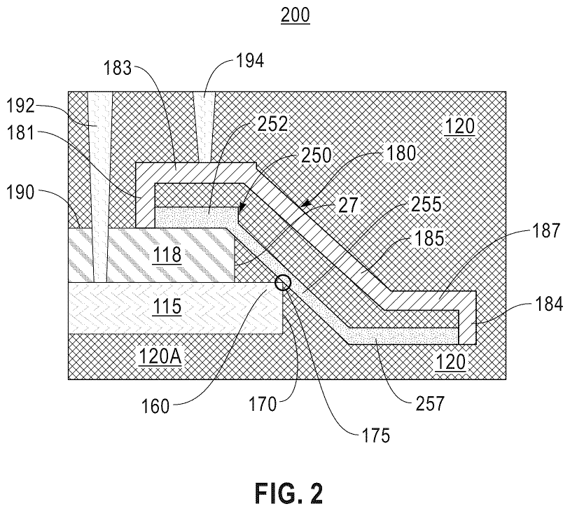

As shown in FIG. 1A there is depicted a cross-sectional view of an exemplary phase change material (PCM) memory device 10 according to a first embodiment of the present disclosure.

The PCM memory device 10 according to a first embodiment is a vertically integrated PCM device including a first dielectric material layer 12, the first dielectric material layer having an extended portion 12A including a planar surface upon which is built a bottom electrode structure 15 of the high aspect ratio PCM cell device 50. A second dielectric material layer 18 is formed above the first dielectric material layer 12 and is formed into two portions separated by a space or gap 25, with one second dielectric material layer portion 18A formed above the bottom electrode 15 and extending proximate to or near a distal end 16 of the bottom electrode 15 but not fully covering the surface of bottom electrode 15. The first dielectric material layer 12 includes a portion abutting a side edge 17 of the bottom electrode structure 15 and extending upward to fill the space or gap 25 formed between the second dielectric material layer 18 and second dielectric material layer portion 18A formed on top the bottom electrode. In an embodiment, the second dielectric material layer 18 and second dielectric material layer portion 18A have respective surfaces 19, 19A that are co-planar.

The PCM cell device 10 of FIG. 1A further includes the PCM cell which is a high aspect ratio PCM memory cell structure 50 including a first PCM cell portion 52 built on a surface of the second dielectric material layer portion 18A with cell portion 52 extending beyond an edge 27 of the second dielectric material layer portion 18A. From this extended portion is formed an angled PCM material channel portion 55 that extends downward at an angle within the gap 25 formed between the second dielectric material layer 18 and second dielectric material layer portion 18A and further extending to within first dielectric material layer 12. The downward angled PCM channel portion 55 is embedded within the first dielectric material layer 12 and includes a flattened or bottom PCM channel portion 57 within the first dielectric material layer 12. The PCM memory cell structure 50 includes a further vertical PCM material channel portion 58 that extends from the bottom PCM channel portion 57 through the gap 25 and having a PCM channel portion 60 terminating at a top surface of the second dielectric material layer 18.

In accordance with an embodiment, the bottom electrode structure 17 includes an upper surface edge providing a point of contact 75 with the angled PCM channel portion 55 of the high aspect ratio PCM cell device structure.

In FIG. 1A a contiguous top electrode layer 80 is formed within the top dielectric material layer 12 above the PCM cell structure 50 including a first horizontally extending foot portion 82 formed on top the surface 19A of the second dielectric material layer 18A and abutting and electrically contacting a side edge of the first PCM cell portion 52 built on the surface of the second dielectric material layer portion 18A and including a further horizontally extending foot portion 84 formed on top the surface of the second dielectric material layer 18 and abutting and electrically contacting a side edge of the PCM cell channel portion 60 built on the surface of the second dielectric material layer portion 18. In view of FIG. 1A, top electrode 80 is disposed horizontally within dielectric material layer 12 above the PCM memory cell structure 50 and include vertical portions at each end connecting the respective extended foot portion 82 and 84 and defining a span that overlies each of the PCM cell channel portions 52, 55, 57, 58 and 60 of PCM memory cell structure 50.

In an embodiment, formed above and electrically contacting the top electrode 80 is a conductive pad 94, e.g., a via structure of metal material that extends upward beyond a top surface of top dielectric layer 12 for electrical connection to other circuits or structures such as a bitline conductor of a memory system (not shown). Similarly formed above and electrically contacting the bottom electrode 15 is a conductive pad 92, e.g., a via structure of metal material that contacts the bottom electrode 15 and extends upward from the bottom electrode through dielectric layers 12, 18A and extends beyond a top surface of top dielectric layer 12 for electrical connection to other circuits or structures such as a wordline conductor of a memory system (not shown).

The embodiment of FIG. 1A depicts diagonal phase change memory cell 10 that achieves a large aspect ratio. Here, the span of the PCM channel 50 including angled PCM channel portion 55 and bottom PCM channel portion 57 is increased without increasing the footprint of the device 10. This is achieved by creating PCM channels at an angle in the dielectric material layer 18 relative to a surface of the dielectric material layer 12. Furthermore, the device structure 10 of FIG. 1A uniquely enables point contact 75 between the PCM channel 50 and the electrode 15, providing high programming efficiencies.

FIG. 1B shows a variation of the PCM cell of FIG. 1A. In view of FIG. 1B, PCM cell memory device 100 is shown including the same structure as the PCM cell memory device structure 10 in FIG. 1A however, a PCM cell structure 150 includes an increased horizontally extended PCM cell channel foot portion 61 built on the surface of the second dielectric material layer portion 18 in the PCM device structure 100 of FIG. 1B. Thus, in the PCM device structure 100 of FIG. 1B, a vertical side portion 98 of the top electrode 90 extends to and electrically connects with a top surface 62 of PCM cell channel foot portion 61 of PCM cell device structure 150 shown at top of the second dielectric layer 18. As in the PCM cell device 10 of FIG. 1A, the embodiment of FIG. 1B depicts a diagonal phase change memory cell 100 that achieves a large aspect ratio. Here, the span of the PCM channel 150 including angled PCM channel portion 55 and bottom PCM channel portion 57 is also increased without increasing the footprint of the device 100. This is achieved by creating PCM channels at an angle in the dielectric material layer 18 relative to a surface of the dielectric material layer 12. Furthermore, the device structure 100 of FIG. 1B enables the point contact 75 between the PCM channel 150 and the electrode 15, providing high programming efficiencies.

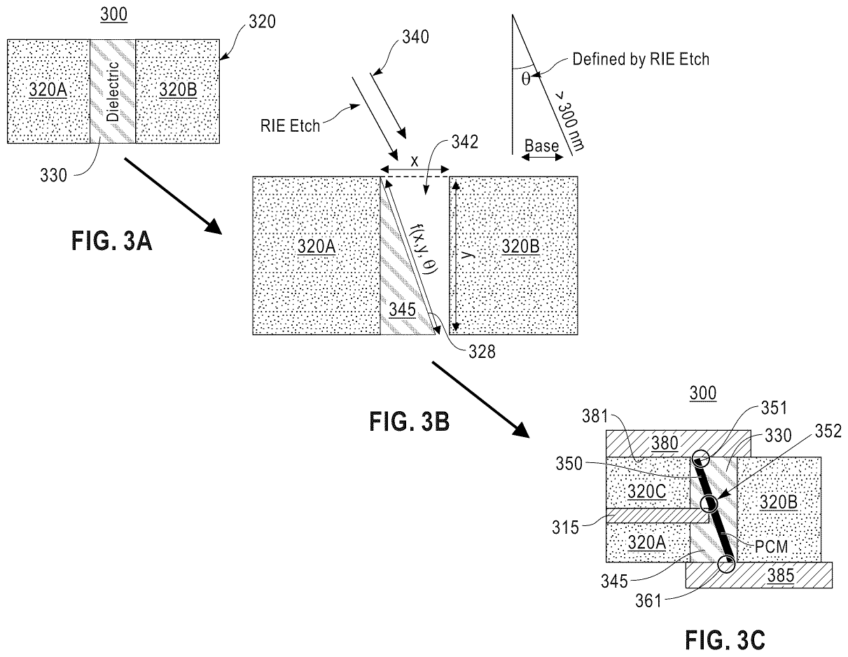

As shown in FIG. 2 there is depicted a cross-sectional view of an exemplary phase change material (PCM) memory device 200 according to a further embodiment of the present disclosure.

The PCM memory device 200 according to the further embodiment is a vertically integrated PCM device including a first dielectric material layer 120, the first dielectric material layer having an extended portion 120A including a planar surface upon which is built the bottom electrode structure 115 of the high aspect ratio PCM cell device 250. A shortened second dielectric material layer 118 is formed above the bottom electrode 115 and extending proximate to or near a distal end 160 of the bottom electrode 115 but not fully covering the surface of bottom electrode 115. The first dielectric material layer 120 includes a portion abutting a side edge 170 of the bottom electrode structure 115 and extends upward to fill the space above the PCM cell device 250.

The PCM cell device 100 of FIG. 2 further includes the PCM cell which is a high aspect ratio PCM memory cell structure 250 including a first PCM cell portion 252 built on a surface of the shortened second dielectric material layer portion 118 with cell portion 252 extending beyond an edge 27 of the second dielectric material layer portion 118. From this extended portion is formed an angled PCM material channel portion 255 that extends downward at an angle within the first dielectric material layer 120. The downward angled PCM channel portion 255 is embedded within the first dielectric material layer 120 and includes a flattened or bottom PCM cell channel portion 257 within the first dielectric material layer 120.

As further shown in FIG. 2, a contiguous top electrode layer 180 is formed within a top dielectric material layer 120 above the PCM cell structure 250. The top electrode layer 180 includes a first vertical portion 181 formed on top the surface 190 of the second dielectric material layer 118 and abutting and electrically contacting a side edge of the first PCM cell portion 252 built on the surface of the second dielectric material layer portion 118; a horizontally extending top electrode portion 183; a downward angled diagonal portion 185 embedded within the first dielectric material layer 120 that extends downward at an angle that is equal to the angle of the angled PCM channel portion 255; a further horizontally extending top electrode portion 187 formed within the first dielectric material layer 120; and a further second vertical portion 184 formed within the first dielectric material layer 120 and abutting and electrically contacting a side edge of the flattened or bottom PCM cell channel portion 257. In view of FIG. 2, top electrode 180 is diagonally disposed within dielectric material layer 120 above the PCM memory cell structure 250 and includes downward angled diagonal portion 185 and including respective horizontal and side vertical portions at each end defining a span that overlies each of the PCM cell channel portions 252, 255, 257 of PCM memory cell structure 250.

As in the PCM cell devices 10,100 of respective FIGS. 1A, 1B, the embodiment of FIG. 2 depicts a diagonal phase change memory cell 200 that achieves a large aspect ratio. Here, the span of the PCM channel 250 including angled PCM channel portion 255 and bottom PCM channel portion 257 is also increased without increasing the footprint of the device 100. This is achieved by creating PCM channels at an angle in the dielectric material layer 118 relative to a surface of the dielectric material layer 120. Furthermore, the device structure 200 of FIG. 2 enables the point contact 175 between the PCM channel 250 and the electrode 115, providing high programming efficiencies. In embodiments depicted, a non-insulating projection liner layer can be formed at the top or bottom of PCM cell channel structures 50, 150, 250 that electrically contact the top electrode.

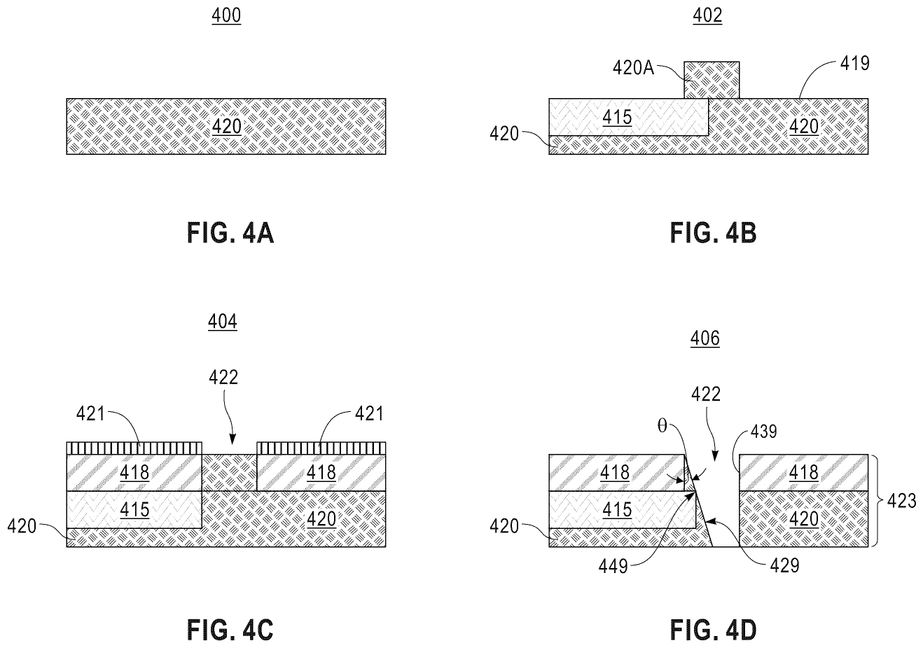

In the embodiments shown in FIGS. 1A, 1B and 2, the respective PCM channel structures 50, 150, 250 are amenable to standard material deposition schemes such as both PVD and ALD and can be created at precise angles. FIGS. 3A-3C depict the forming of the PCM memory cell 300 including the diagonal channel 350 disposed at an angle θ. As shown in FIG. 3A, the semiconductor manufacturing steps employed include forming a dielectric material structure 320, and patterning resist, etching, and depositing within the structure a pillar structure 330 of another dielectric material that separates the dielectric material layer into two portions 320A, 320B. In FIG. 3B, after patterning the pillar dielectric structure 330, there is conducted an angled reactive ion etch (RIE) 340 at the patterned pillar dielectric structure 330. This RIE is performed at an angle θ and results in the removal of dielectric material in the pillar structure 330 to provide an opening 342. In an embodiment, the angle θ can range anywhere from between 5° to 75°, but typically between 10° to 60° and is controlled by ion optics. Any angled RIE technique can be used including directional etch, flared etch, or angled ion beam etching using standard tools with optimized plasma chemistries to create the diagonal type PCM cell. In view of FIG. 3B, a remaining portion 345 of the pillar structure is triangular shaped and includes an exposed angled sidewall 328 of a length that is a function of the horizontal distance “x” of the pillar 330, the vertical height “y” of the pillar 330 and the RIE etching angle θ. That is, the length “l” of the angled sidewall is a function of (x, y, θ). In embodiments, the length of the angled sidewall dictates the length of the PCM cell channel and can range from between 50 nm to 500 nm dependent upon both the x- and y-directions. In a non-limiting embodiment, the PCM diagonal length can be about 300 nm and reduces the footprint of the device. The thickness of the channel can be from 1 nm to 50 nm.

Further, as shown in FIG. 3C, prior to forming the pillar structure 330, there can be patterned and formed a bottom metal electrode 315 separating the first dielectric material into portions 320A, 320C. This bottom electrode 315 can be extended out so an edge of the bottom electrode can protrude into the formed dielectric material pillar 330. Then, after performing the angled RIE etch of the pillar structure, an edge of the bottom electrode is exposed along sidewall 328. The next step includes the deposition of the PCM cell channel material that conforms to the angled sidewall surface 329 of the pillar dielectric material of the remaining triangular structure 345 to result in forming diagonal-type PCM memory cell channel structure 350. The diagonal-type PCM memory cell channel structure material is deposited within the opening 342 to form diagonal-type PCM memory cell channel structure 350 that contacts the exposed edge of the bottom electrode 315 making a point contact or tip/edge or line contact 352 of the bottom electrode and the PCM cell channel 350. In a non-limiting embodiment, bottom electrode contact area with the PCM channel can range from about 5.0 nm² to about 300 nm². In one embodiment, the bottom electrode contact area with the PCM channel is about 20 nm². Once the PCM cell channel 350 is formed the pillar structure opening is again filled and the structure top surface planarized and a further top metal electrode 380 is deposited on the top surface that provides another point of contact 351 between the top electrode and the PCM cell channel 350. Alternatively, or in addition, a further top metal electrode 385 can be formed at an opposing surface that can provide another point of contact 361 between the top electrode and the PCM cell channel 350

Thus, as shown in FIG. 3C, the PCM cell structure 300 includes first dielectric material layer portions 320A, 320C and a separated first dielectric material portion 320B, a bottom electrode 315 formed on the first dielectric material layer portion 320A; the second dielectric material layer portion 320C formed on top the bottom electrode 315, and a top electrode 380 formed at a top surface of the second dielectric material layer portion 320C. A remaining triangular portion 345 of the pillar dielectric material structure 330 abuts side edges of the first dielectric material layer portions 320A, 320C. The bottom metal electrode 315 extends horizontally within remaining triangular portion 345 beyond the side edge of both the first dielectric material layer portion 320A and the second dielectric material layer portion 320C. As shown in FIG. 3B, the diagonal-type PCM memory cell channel material is deposited within opening 342 onto the side edge 328 of the pillar dielectric triangular portion 345 to form the diagonal PCM memory cell channel structure 350 conforming to the angle defined by the RIE etch angle. As shown in FIG. 3C, the PCM cell channel structure 350 is inclined at an angle θ that ranges from between 5° and 75° (i.e., 5°<θ<75°) relative to a vertical axis. This angle θ is defined by a reactive ion etching (RIE) technique applied to remove portions of the pillar structure dielectric material 330. As shown in the PCM memory cell 300 of FIG. 3C, the bottom electrode 315 includes an edge 352 that contacts an underlying surface of the PCM cell channel structure 350 defining a single point of electrical contact between the bottom electrode 315 and the PCM cell channel structure 350. The diagonal PCM memory cell channel structure 350 includes a top portion having an edge 351 electrically contacting an underside surface 381 of the top electrode 380. In an embodiment, the PCM cell channel structure 350 is greater than about 300 nm in length and defines a small base with a long PCM channel. Thus, the embodiments of FIGS. 1A, 1B, 2 provide for long phase-change material channels at reduced lateral areal footprints. Such structures further simultaneously enable very low programming energies in devices while achieving a small area footprint.

In the embodiments herein, the diagonal-type PCM memory cell can be disc-shaped with the PCM channel created at precise angles depending upon the angle of the RIE etch performed to remove the dielectric material portion 330. Further, the bottom electrode 315 does not require application of any chemical-mechanical-planarization (CMP) techniques and when formed, the device 300 achieves an annulus-shaped amorphous plug shape. Further, as shown in FIG. 3C, the top electrode 380 can make surface or edge contact of the PCM channel 350. Further, the performed angled RIE etch to remove the dielectric material portion 330 to form the angled PCM cell channel structure 350 circumvents etch damage to the phase change material active area.

In the embodiment depicted in FIGS. 3A-3C, there can first be deposited a diagonal projection liner material layer prior to depositing the diagonal PCM cell channel material forming diagonal PCM channel structure 350 and can include projection liner portions (not shown) formed at the top or bottom surface of the PCM cell channel structure 350 that must electrically contact the top electrode. The projection liner layer can be of a liner material of a length to mitigate device reset state non-idealities and contribute to the reduction of set/intermediate conductance states. In a further embodiment, a threshold voltage (Vth) reduction layer can be formed at the top or bottom of the PCM cell channel structure 350. For example, rather than a single PCM layer, a sandwich of two or more further functional layers including the PCM layer can be formed. For example, a tri-layer including metal-containing (e.g., metal nitrides) layers sandwiching the PCM layer can be formed in between to enable a resistance tuning and function as a Vth (a threshold voltage) reduction layer which reduces the voltage required to switch the phase (state) of the phase change material.

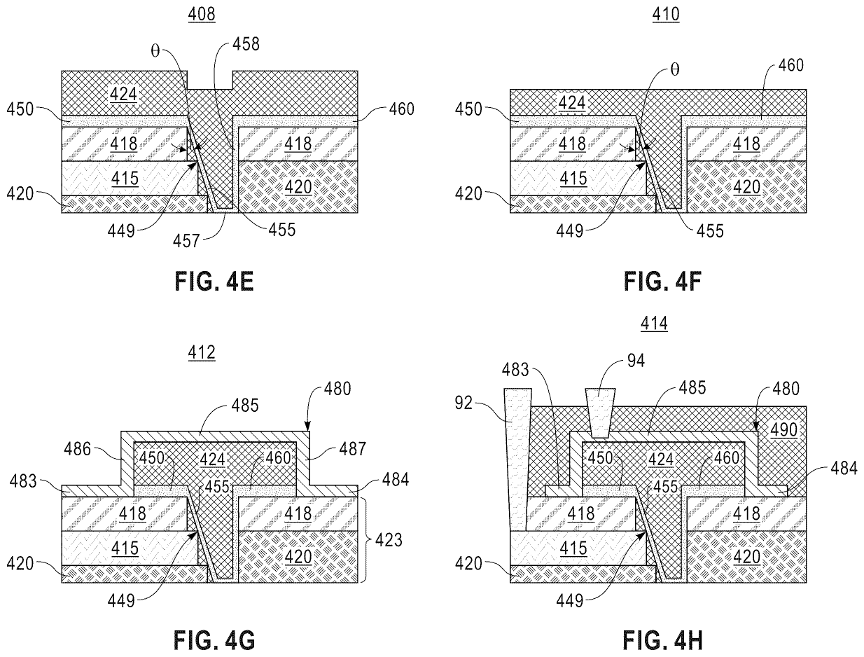

FIGS. 4A-4H depict method steps for constructing a phase change memory device according to the embodiments depicted herein. As shown in FIG. 4A, there is depicted a structure 400 resulting from initial semiconductor manufacturing steps of forming a dielectric material layer 420, e.g., using an atomic layer deposition (ALD) technique. In an embodiment, the dielectric material layer 420 is SiO₂ although can be Silicon Nitride (SiN), Al₂O₃ or other dielectric materials and can be deposited to a thickness ranging up to 30 nm +/−0.5 nm. Alternately, the thickness of dielectric material layer 420 can be 200 nm or greater.

FIG. 4B depicts an intermediate semiconductor memory structure 402 resulting after performing a photolithographic semiconductor process that includes the patterning and depositing of a bottom electrode (BE) structure 415 on top the first dielectric material layer 420. Further shown is the result of extending the dielectric material layer 420 with an optional CMP if needed, to form a coplanar top surface 419. A further dielectric material layer can be patterned and deposited to further form a patterned dielectric cap 420A spanning a surface 419 above a portion of the bottom electrode 415 and a portion of first dielectric material layer 420. The steps of FIG. 4B refer to the patterning/transferring of the bottom electrode (BE) including the depositing of sub-10 nm thick BE metal material on the dielectric substrate 420.

Illustrative examples of electrically conductive electrode materials that can be used in providing bottom electrode layer 415 include, but are not limited to: titanium nitride (TiN), tantalum nitride (TaN), ruthenium (Ru), cobalt (Co), nickel (Ni), copper (Cu), tungsten (W), tungsten nitride (WN), silver (Ag), platinum (Pt), palladium (Pd), aluminum (Al), or any suitable combination of those materials. The bottom electrode layer 415 can include a single electrically conductive electrode material or a multilayered stack of electrically conductive materials. The bottom electrode layer 415 can be formed utilizing a deposition process such as, for example, chemical vapor deposition (CVD), plasma enhanced chemical vapor deposition (PECVD), physical vapor deposition (PVD), atomic layer deposition (ALD), sputtering or plating. The bottom electrode layer 415 can have a thickness from about 10 nm to about or exceeding 200 nm; although other thicknesses (e.g., sub-10 nm) are contemplated and can be used in the present application (e.g., even up to 1 micron in thickness). In an embodiment, the bottom electrode can be lithographically patterned into lateral strips of the following dimensions: e.g., width =sub-10 nm and length =sub-100 nm. In an embodiment, bottom electrode 415 can be in electrical contact with a transistor device (not shown) in order to provide a current used to program (e.g., SET or RESET) a formed PCM memory cell structure (not shown).

In an embodiment, the formed bottom electrode can be a smaller diameter and/or width than the width of PCM cell channel structure to be formed and dimensioned to apply electrical current to melt and/or permit the PCM material cell portion to undergo a phase change. Bottom electrode can be composed of an electrically conductive electrode material such as a metal-nitride (e.g., TiN, TaN) or other doped metal materials as known in the art.

FIG. 4C depicts an intermediate semiconductor memory structure 404 resulting after performing a photolithographic semiconductor process that includes depositing a further (e.g., second) dielectric material layer 418 on and at either side of the first dielectric material cap layer 420A in the structure 402 of FIG. 4B. The structure 404 of FIG. 4B further results after performing a further CMP step to planarize a top surface of the second dielectric material layer 418 and after applying further lithographic steps to deposit a top photoresist layer 421 above the second dielectric material layer 418, patterning, and conducting an etch to remove the resist portion above the cap layer 420A to form an opening 422. This formed opening 422 in the remaining structure 404 is used to conduct the further angled etch to create the diagonal PCM structure. Various semiconductor manufacturing processes (choice of lithography and resists) can be used to create the structure. In one embodiment, this can be performed using a processing step that spin coats HSQ (Hydrogen silsesquioxane) to form the resist layer 421 that hardens into an oxide (e.g., the SiO₂) for facilitating subsequent lithographic patterning steps.

FIG. 4D depicts an intermediate semiconductor memory structure 406 resulting after performing semiconductor processes including the angled RIE etching through the formed opening 422 in the structure 404 of FIG. 4C to remove portions of the capping layer 420A and remove portions of the first dielectric material layer 420 to form an angled side edge 429 that exposes an edge of the bottom electrode 415. In an embodiment, through opening 422 an angled RIE (e.g., 10°<θ<60° relative to a vertical) is conducted to result in a slanted side edge 429 of the second dielectric material layer 418, the exposed edge of bottom electrode 415 and the first dielectric material layer 420 on one side and leaving a straight sidewall edge 439 of the second dielectric material layer 418 and the first dielectric material layer 420 on an opposite side thereby forming a dielectric material layer stack 423. Alternatively, several reactive angled ion etches can be conducted at many different angles (e.g., as a function of the x-axis direction) to form the slanted side edge 429 of the second dielectric material layer 418, the exposed edge of bottom electrode 415 and the first dielectric material layer 420 on one side and leaving a straight sidewall edge 439 defining a sidewall of the formed dielectric material layer stack 423. In an embodiment, the conducted angled RIE within opening 422 is such that a side edge of the bottom electrode includes a portion 449 exposed at the etched angle. In an alternate embodiment, to achieve this, one or more controlled timed etches at different etch selectivities can be conducted, e.g., by conducting a first RIE through opening 422 using an etch chemistry at a first etch rate, e.g., that is selective to the first dielectric layer material 418 and then conducting a second RIE through opening 422 using a different etch chemistry at a different etch rate, e.g., that is selective to the second dielectric layer material 420. The resulting structure 406 of FIG. 4D further reflects the results of removing the top patterned photoresist layer 421 from the surface of the structure 404 of FIG. 4C. Besides RIE, another angled etch technique can be implemented, e.g., tilting of the substrate holder, angled ion beam etching, inductive coupled plasma (ICP) etch, or other wet/dry etch techniques using tools with optimized plasma chemistries that can create diagonal-type PCM cells.

FIG. 4E depicts an intermediate semiconductor memory structure 408 resulting after performing an ALD deposition step through opening 422 to deposit PCM material to form the thin PCM memory cell channel 450. As shown in FIG. 4E, the PCM material is deposited using ALD to result in forming a PCM material layer 450 above the second dielectric material layer 418 and further forming an angled PCM channel portion 455 that conforms to the slanted edge 429 of the stack of structures shown inside opening 422 in the structure of FIG. 4D. Further shown in FIG. 4E is a further formed bottom horizontal PCM channel portion 457, a vertical PCM channel portion 458 that conforms to the opposite inner vertical sidewall edge 439 of the dielectric material layer stack 423 shown inside opening 422 in the structure of FIG. 4D, and a top PCM channel portion 460 disposed above the opposing second dielectric material layer 418 of stack 423. The structure 408 shown in FIG. 4E further reflects a result of further depositing a thick trench dielectric material 422 within the opening of the memory cell defined by the angled PCM channel portion 455, the bottom horizontal PCM channel portion 457, and the vertical PCM channel portion 458 that conforms to the opposite inner vertical sidewall 439 of the stack 423. As shown in FIG. 4E, the deposited dielectric material further forms a top layer 424 above the PCM memory cell channel portions 450, 460.

In the structure 408 of FIG. 4E, the angled PCM channel portion 455 that conforms to the slanted edge 429 is in electrical contact with the exposed top edge of the bottom electrode 450 providing a thin edge point of contact. In embodiments, prior to forming the angled PCM channel portion 455, there can be first formed a thin projection liner material layer (not shown) of a non-insulating, non-switching material on the slanted portion of the formed opening, with the PCM material forming the diagonal PCM channel portion above the diagonal (slanted) projection liner layer. The projection linter material layer (not shown) permits for reduced temporal changes (drift and noise) of the PCM cell.

In an embodiment, the deposited PCM memory cell channel 450 includes any material that undergoes a phase change from crystalline to amorphous or vice versa when energy is applied thereto whereby the electrical properties of the material also change. In embodiments, the phase change material (PCM) that can be used for PCM layer 450 includes a chalcogenide that contains an element from Group 16 (i.e., a chalcogen) of the Periodic Table of Elements.

Examples of chalcogens that can be used as the phase change material include, but are not limited to, a GeSbTe alloy (GST), a SbTe alloy, or an InSe alloy. Other materials such as, for example, Cr₂Ge₂Te₆ (CrGeT), can also be used as the phase change material so long as this other material can retain separate amorphous and crystalline states. Alternatively, other suitable materials for the phase change material include Si—Sb—Te (silicon-antimony-tellurium) alloys, Ga—Sb—Te (gallium-antimony-tellurium) alloys, Ge—Bi—Te (germanium-bismuth-tellurium) alloys, In—Se (indium-tellurium) alloys, As—Sb—Te (arsenic-antimony-tellurium) alloys, Ag—In—Sb—Te (silver-indium-antimony-tellurium) alloys, Ge—In—Sb—Te alloys, Ge—Sb alloys, Sb—Te alloys, Si—Sb alloys, and combinations thereof. In some embodiments, the phase change material can further include nitrogen, carbon, and/or oxygen. In some embodiments, the phase change material can be doped with dielectric materials including but not limited to aluminum oxide (Al₂O₃), silicon oxide (SiO₂), tantalum oxide (Ta₂O₅), hafnium oxide (HfO₂), zirconium oxide (ZrO₂), cerium oxide (CeO₂), silicon nitride (SiN), silicon oxynitride (SiON), etc. PCM layer 450 can be formed utilizing a deposition process such as, for example, CVD, PECVD, PVD, or ALD. The PCM material layer 450 can be deposited using atomic layer deposition to a thickness ranging from about 2 nm to 15 nm, e.g., about 1 nm -50 nm thick, and takes the shape of the slanted side edge 429.

FIG. 4F depicts an intermediate semiconductor memory structure 410 resulting after conducting a further CMP step to planarize the top surface of a top dielectric material layer 424 of the structure 408 of FIG. 4E.

FIG. 4G depicts an intermediate semiconductor memory structure 412 resulting after performing semiconductor processes including the RIE etching and/or ion milling to remove dielectric material layer portions 424 and their underlying edge portions of the top horizontal PCM channel portions 450, 460 of the PCM memory cell channel and the depositing of a top electrode (TE) metal material for forming the top electrode 480. In particular, the deposited TE material is formed at removed PCM material portions such that the TE material includes a TE horizontal portion 483 formed on a top of the second dielectric material layer 418 and abutting the PCM material memory cell channel portion 450 and includes a TE horizontal portion 484 formed on a top of the second dielectric material layer 418 of stack 423 and abutting the PCM material memory cell channel portion 460. Further lithographic steps are performed to pattern and define resist structures (not shown) that are used to define a top electrode structure 480 including TE metal material deposition forming vertical portions 486, 487 extending from respective TE horizontal portion 483 and TE horizontal portion 484 and the TE metal material deposition forming a top TE horizontal portion 485 above the remaining portion of second dielectric material layer 424.

In an alternate embodiment such as shown in FIG. 1B, the structure 412 of FIG. 4G can be modified to ensure placement of an underside edge of the formed top electrode vertical portion 487 on the surface of the PCM material channel portion 460 as in the embodiment of FIG. 1B. Further alternate embodiments contemplate that the top electrode 480 can make surface or edge contact to a PCM material layer. That is, a first end of the top electrode can be patterned and formed to make electrical contact with one or more of: a top surface of the first PCM layer portion 450 or a sidewall edge of the first PCM layer portion 450 formed on the second dielectric material layer 418, and similarly a second end of top electrode 480 can be patterned and formed to make electrical contact with one or more of: another location of the top surface of the second PCM layer portion 460 or a sidewall edge of the second PCM layer portion 460.

Illustrative examples of electrically conductive electrode materials that can be used in providing top electrode layer 480 include, but are not limited to: titanium nitride (TiN), tantalum nitride (TaN), ruthenium (Ru), cobalt (Co), nickel (Ni), copper (Cu), tungsten (W), tungsten nitride (WN), silver (Ag), platinum (Pt), palladium (Pd), aluminum (Al), or any suitable combination of those materials. The top electrode layer 480 can include a single electrically conductive electrode material or a multilayered stack of electrically conductive materials. The top electrode layer 480 can be formed utilizing a deposition process such as, for example, chemical vapor deposition (CVD), plasma enhanced chemical vapor deposition (PECVD), physical vapor deposition (PVD), atomic layer deposition (ALD), sputtering or plating.

FIG. 4H depicts a structure 414 resulting after performing a dielectric material deposition step to deposit further dielectric material layer 490 above the formed top electrode top layer 485 and to the sides and above the horizontal portions 483, 484 of top electrode 480. The formed structure 414 of FIG. 4H further reflects a result of via etching steps to form the respective via openings to be filled with conductor metal material used to form respective pads for connecting respective bottom electrode 415 and top electrode 480 to further devices or circuits (not shown) in further back-end-of-line (BEOL) processes. Then, a via pad metal material deposition step is performed to deposit conductive metal material to form the bottom electrode pad 92 and top electrode pad 94 that each extend to beyond the top surface of the resulting structure, e.g., for further connection to respective wordline or bitline conductors of a memory system (not shown). In alternative embodiments, process can include opening vias and forming the bottom electrode pad 92 and top electrode pad 94 that each extend down beyond a bottom surface of the resulting structure.

In an embodiment, the methods described in view of FIGS. 4A-4H can produce a diagonal phase change memory cell 450 such as shown in FIG. 2 using similar semiconductor processing steps however, that does not include the forming or etching of a via so the PCM will land on the substrate and follow the surface topography of the substrate surface. Based on patterning, the top electrode will also follow the angle of the PCM channel as shown in the PCM cell of FIG. 2.

The methods described in view of FIGS. 4A-4H produces a diagonal phase change memory cell 450 that achieves a large aspect ratio. In an aspect, the span of the PCM cell channel is increased without increasing the footprint of the device which is achieved by creating PCM channels at an angle in a first dielectric material layer, e.g., layer 418, relative to the second dielectric material layer 420. This device structure uniquely enables point (e.g., electrode edge) contact between the PCM channel and the electrode, providing high programming efficiencies. That is, the bottom electrode can make surface or edge contact of the PCM. Further, a projection liner material layer can be integrated with the formed top or bottom PCM channel to reduce any conductance drift and mitigate noise. While the projection liner has little effect on SET-state drift (crystalline phase), it substantially reduces drift for RESET states (amorphous phase) and improves the overall noise across SET and RESET states.

In embodiments, dependent upon the RIE etch angle, the PCM channel 455 can be created at precise angles. Each of the formed structures are amenable to standard material deposition schemes such as both physical vapor deposition (PVD) and ALD are covered.

Further, the PCM memory cell design of FIGS. 1A, 1B and 2 provide for a large integration density compared to liner cell type device technologies. There is further achieved enhanced programming efficiencies due to the reduced electrode contact areas and confined phase change material volume. There is further achieved a large conductance window from the larger span of the PCM memory cell channel. Further, the PCM memory cell design of FIGS. 1A, 1B and 2 permits low conductance values in the SET and RESET states formed in ultra-thin PCM channel.

While the present application has been particularly shown and described with respect to preferred embodiments thereof, it will be understood by those skilled in the art that the foregoing and other changes in forms and details may be made without departing from the spirit and scope of the present application. The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. It is therefore intended that the present application not be limited to the exact forms and details described and illustrated, but fall within the scope of the appended claims.

What is claimed is:

1. A phase change memory cell comprising:
a first dielectric material layer;
a first electrode formed above the first dielectric material layer;
a second dielectric material layer formed above the first electrode;
a further dielectric material structure having a first sidewall surface portion abutting a side edge of the first dielectric material layer and a second sidewall surface portion abutting a side edge of the second dielectric material layer; and
a phase change material (PCM) layer having a first PCM layer portion formed on a top surface of said second dielectric material layer and having an angled PCM layer portion extending from the first PCM layer portion at an angle within said further dielectric material structure and having a slanted surface, the first electrode having an edge electrically contacting the slanted surface of the angled PCM layer.

2. The phase change memory cell of claim 1, wherein the angle ranges from between 5° and 75° relative to a vertical.

3. The phase change memory cell of claim 1, wherein the first electrode is of a length extending beyond a length of the second dielectric material layer.

4. The phase change memory cell of claim 1, wherein a dielectric material of the first dielectric material layer is different than a dielectric material of the second dielectric material layer.

5. The phase change memory cell of claim 1, wherein a dielectric material of the further dielectric material structure is the same dielectric material as the first dielectric material layer.

6. The phase change memory cell of claim 1, wherein the first dielectric material layer, the first electrode formed above the first dielectric material layer and the second dielectric material layer form a first stack structure, said memory cell further comprising:
a second stack structure comprising a layer of the first dielectric material and the second dielectric material layer formed thereon, the second stack structure separated from said first stack by the further dielectric material structure and having a sidewall edge, wherein the angled PCM layer portion extends to a predetermined depth within the further dielectric material layer between said first and second stacks, said PCM layer further comprising:
a horizontal PCM layer portion extending from said angled PCM layer portion to the sidewall edge of said second stack within said further dielectric material structure;
a vertical PCM layer portion extending vertically from said horizontal PCM layer portion along the sidewall edge of said second stack; and
a second PCM layer portion extended from said vertical PCM layer portion and formed on a top surface of the second stack.

7. The phase change memory cell of claim 6, further comprising:
a second electrode having a first end electrically contacting the first PCM layer portion formed on said first stack and having a second end electrically contacting the second PCM layer portion formed on said second stack.

8. The phase change memory cell of claim 7, wherein the first end of said second electrode makes electrical contact with one or more of: a top surface of the first PCM layer portion or a sidewall edge of the first PCM layer portion on said second dielectric material layer of said first stack.

9. The phase change memory cell of claim 7, wherein the second end of said second electrode makes electrical contact with one or more of: a top surface of the second PCM layer portion or a sidewall edge of the second PCM layer portion on said second dielectric material layer of said second stack.

10. The phase change memory cell of claim 6, further comprising:
a projection liner material layer disposed beneath the angled PCM layer portion, the projection liner material layer comprising a resistive non-switching material.

11. A phase change memory cell comprising:
a first dielectric material layer;
a first electrode formed above the first dielectric material layer;
a second dielectric material layer formed above the first electrode;
a further dielectric material structure having a first sidewall surface portion abutting a side edge of the first dielectric material layer and a second sidewall surface portion abutting a side edge of the second dielectric material layer;
a phase change material (PCM) layer having a first PCM layer portion formed on a top surface of said second dielectric material layer and having an angled PCM layer portion extending from the first PCM layer portion at an angle within said further dielectric material structure and having a second PCM layer portion extending from said angled PCM layer portion within said further dielectric material structure, said angled PCM layer having a slanted surface, wherein an edge of the first electrode electrically contacts the slanted surface of the angled PCM layer; and
a second electrode having a first end electrically contacting the first PCM layer portion and having a second end electrically contacting the second PCM layer portion within said further dielectric material structure.

12. The phase change memory cell of claim 11, wherein the second electrode comprises an angled portion, the angled second electrode portion extending at an angle substantially parallel with the angled PCM layer portion.

13. The phase change memory cell of claim 11, wherein the angle ranges from between 5° and 75° relative to a vertical.

14. The phase change memory cell of claim 11, wherein the first electrode is of a length extending beyond a length of the second dielectric material layer.

15. The phase change memory cell of claim 11, wherein a dielectric material of the first dielectric material layer is different than a dielectric material of the second dielectric material layer.

16. The phase change memory cell of claim 11, wherein a dielectric material of the further dielectric material structure is the same dielectric material as the first dielectric material layer.

17. The phase change memory cell of claim 11, wherein the first end of said second electrode makes electrical contact with one or more of: a top surface of the first PCM layer portion or a sidewall edge of the first PCM layer portion on said second dielectric material layer; and the second end of said second electrode makes electrical contact with one or more of: another location of said top surface of the second PCM layer portion or a sidewall edge of the second PCM layer portion.

18. The phase change memory cell of claim 11, further comprising:
a projection liner material layer disposed beneath the angled PCM layer portion, the projection liner material layer comprising a resistive non-switching material.

19. A method of forming a phase change memory cell comprising:
providing a first dielectric material layer having a first portion of a first thickness and a second portion of a second thickness;
forming a bottom electrode on top of the first portion of the first dielectric material layer, the bottom electrode having a surface that is coplanar with a surface of the second portion of the first dielectric material layer;
forming a capping dielectric material layer on top said coplanar surface, said capping dielectric material layer of a width covering an interface between a sidewall edge of the bottom electrode and the second portion of the first dielectric material layer;
forming a second dielectric material layer on top of the bottom electrode, wherein a length of said second dielectric material layer is of a length less than the length of the bottom electrode, said second dielectric material layer having a surface coplanar with a surface of the capping dielectric material layer;
performing a reactive ion etch at a defined angle to form an opening extending through said capping layer and said first dielectric material layer, the opening having a continuous slanted sidewall surface comprising a slanted sidewall surface portion of said capping dielectric material layer and a slanted sidewall surface portion of said first dielectric material layer, the angled etch exposing an edge of the bottom electrode on the continuous slanted sidewall surface;
depositing a phase change material (PCM) layer on top said continuous slanted sidewall surface to form an angled PCM layer, whereby the edge of the first electrode electrically contacts the slanted surface of the angled PCM layer.

20. The method of claim 19, wherein the defined angle ranges from between 0° and 55° relative to a vertical.
